(19) United States
(12) Patent Application Publication
(10) Pub. No.: US 2008/0191906 A1
(43) Pub. Date: Aug. 14, 2008

(54) Method For Providing An Output Signal For Storing Of User Data On A Data Carrier

(75) Inventors: Cornelis Wilhelmus Clemens Maria Smulders, Eindhoven (NL); Jeannet Van Rens, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/910,471

(22) PCT Filed: Mar. 27, 2006
(86) PCT No.: PCT/IB2006/050919

§ 371 Date: Oct. 2, 2007

(30) Foreign Application Priority Data
Apr. 4, 2005 (EP) 05102614.4

(51) Int. Cl. H03M 7/00

(52) U.S. Cl. 341/50

(57) ABSTRACT

A method for providing an output signal (58) for storing of user data on a data carrier (37) is provided. The method comprises the steps of receiving (11) the user data, encoding (12) the user data according to a predetermined encoding scheme and converting (13) the encoded user data to the output signal (58). The encoding according to the predetermined encoding scheme results in irregular distances between detectable signal elements which have equal signal values and at least a predetermined run length. However for some control loops, said distances should not be too large. According to the invention the step of encoding comprises providing (14b, 15b) additional detectable signal elements in the encoded user data in disagreement with the encoding scheme. Thereby the method results in limiting the distance between the detectable signal elements.

The invention relates to a method for providing an output signal for storing of user data on a data carrier, the method comprising the steps of receiving the user data, encoding the user data according to a predetermined encoding scheme resulting in irregular distances between detectable signal elements which have equal signal values and at least a predetermined run length, and converting the encoded user data to the output signal.

The invention further relates to a device for performing said method and to a data carrier comprising user data which is applied using said method.

In devices for writing data on data carriers, such as CD or DVD, generally the user data is encoded in conformance with some standard encoding scheme. When such a standard encoding scheme is used for the storing of the user data, afterwards it is possible to retrieve the user data using a standard reader device. After encoding, the encoded data is converted to a converted signal. The converted signal is used for driving a power of a laser for writing the data onto the data carrier. Some control loops for controlling the writing process directly or indirectly (after reflection) sample the laser power and, if necessary, adjust one or more write parameters, such as an amplitude of a ‘write power’ level or a ‘bias power’ level.

For example, an ECMA-349 and an ECMA-337 standard are used for encoding data for applying to DVD+R and DVD+RW optical discs. These standards use an encoding scheme wherein 8-bit bytes (e.g. 11101000) of the user data are transformed into 16-bit code words (e.g. 0100100010000100) using a conversion table. Then the 16-bit words are converted to channel bits in a converted signal which signal makes a transition from high to low for every ONE in the 16-bit word and remains high or low for every ZERO. The conversion table is designed such that between 2 ONEs there are always at least 2 ZEROs and at most 10. Due to this limitation, the converted signal comprises run lengths (=the number of consecutive signal elements with equal signal values) between 3 and 11. The converted signal does never change its polarity (high or low) twice within 3 channel bits and at least once within every 11 channel bits.

Due to delays in the control loops, no reliable samples of the laser power can be taken from signal elements with shorter run lengths. In the following, signal elements with a run length which is long enough for reliably sampling the laser power are called detectable signal elements. At low writing speeds it might be possible to reliably sample the laser power on the last part of short or medium-long run lengths. At higher writing speeds only the longer run lengths can be sampled. Long run lengths occur less often than short run lengths. Besides that, the distance between detectable signal elements is determined by the encoding scheme and varies throughout the output signal. Therefore it is not possible to reliably sample the laser signal at a sufficiently high rate. As a consequence, as writing speeds increase, stability of control loops becomes more and more problematic.

It is an object of the invention to provide a method according to the opening paragraph which results in more stable control loops.

According to the invention, this object is achieved by having the step of encoding comprise providing additional detectable signal elements in the encoded user data in disagreement with the encoding scheme, for limiting the distance between the detectable signal elements.

With encoding, data is transformed from one system of communication to another. Input values are transformed to output values. Besides encoded input values, the encoded data may comprise auxiliary data which may be required, for example, for reading or writing the data from or onto a data carrier, for decoding the encoded data or for storing additional data concerning, e.g., the date and time of the encoding.

The encoded values are chosen according to the predetermined encoding scheme. For example, the DVD standard prescribes that the DCC (dc component suppression control) algorithm drives the selection of synchronisation patterns and converted data words. The DCC does this such that the absolute value of the DSV (digital sum value, is difference between number of written ONEs and written ZEROs) at any positions is minimized.

These choices of encoded values may result in irregular distances between detectable signal elements, which results in the aforementioned control loop stability problems. With the method according to the invention these problems are solved by providing additional detectable signal elements in the encoded user data in disagreement with the encoding scheme. The additional detectable elements enable reliably sampling the laser signal at a sufficiently high rate.

The invention takes advantage of the insight of the inventors that some disagreements with the predetermined encoding scheme do not immediately cause serious problems with, e.g., reading the encoded data from the data carrier. Some freedom in the choice of converted values allows for providing the additional detectable signal elements.

In an embodiment of the method according to the invention the encoded user data comprises sequences of signal elements which sequences represent encoded bits of the user data, said signal elements of the sequences have a signal value and a run length according to the predetermined encoding scheme, and the encoding comprises providing the sequences of signal elements with the additional detectable signal elements in disagreement with the encoding scheme.

Conversion may be one to one, i.e. for every input value one converted output value exists, or one to many, i.e. for every input value the converted output is chosen out of several converted output values. In the event of one to many conversion the predetermined encoding scheme will generally describe which choice has to be made. In this embodiment, however, occasionally signal elements are chosen in disagreement with the encoding scheme to limit the distance between the detectable signal elements.

In an embodiment of the method according to the invention the encoded user data comprises synchronization pulses comprising signal elements with at least the predetermined run length, the irregular distances result from irregular signal values for said signal elements of the synchronization pulses, and the encoding comprises providing synchronization pulses with the additional detectable signal elements in disagreement with the encoding scheme.

This embodiment takes advantage of the predetermined encoding scheme allowing for some freedom in the choice of synchronization codes. By occasionally inserting synchronization pulses in the output signal in disagreement with the predetermined encoding scheme, the maximum distance between the detectable signal elements is limited.

According to another aspect of the invention a device is provided, comprising an input for receiving user data, an encoder for encoding the user data according to a predetermined encoding scheme resulting in irregular distances between detectable signal elements with equal signal values and at least a predetermined run length, an encoding control unit for providing additional detectable signal elements in the encoded user data in disagreement with the encoding scheme, for limiting the distance between the detectable signal elements, and an output unit for converting the encoded user data to an output signal for storing of the user data on a data carrier.

Such a device could perform the methods as described above.

An embodiment of the device according to the invention further comprises a laser drive unit for receiving the output signal and providing a laser signal for writing the encoded user data on the data carrier, and at least one feedback circuit for sampling the laser signal and for adjusting a write parameter according to a sampled value of the laser signal corresponding with the detectable signal elements.

In such a device, the feedback circuit can regularly and reliably sample a value of the laser signal which value corresponds to a detectable signal element. Because the distance between the detectable signal elements is limited, the waiting time till a next useful sample can be made is also limited. Such a feedback circuit shows the desired loop stability and thereby improves the stability of the total write process.

These and other aspects of the invention are apparent from and will be elucidated with reference to the embodiments described hereinafter.

In the drawings:

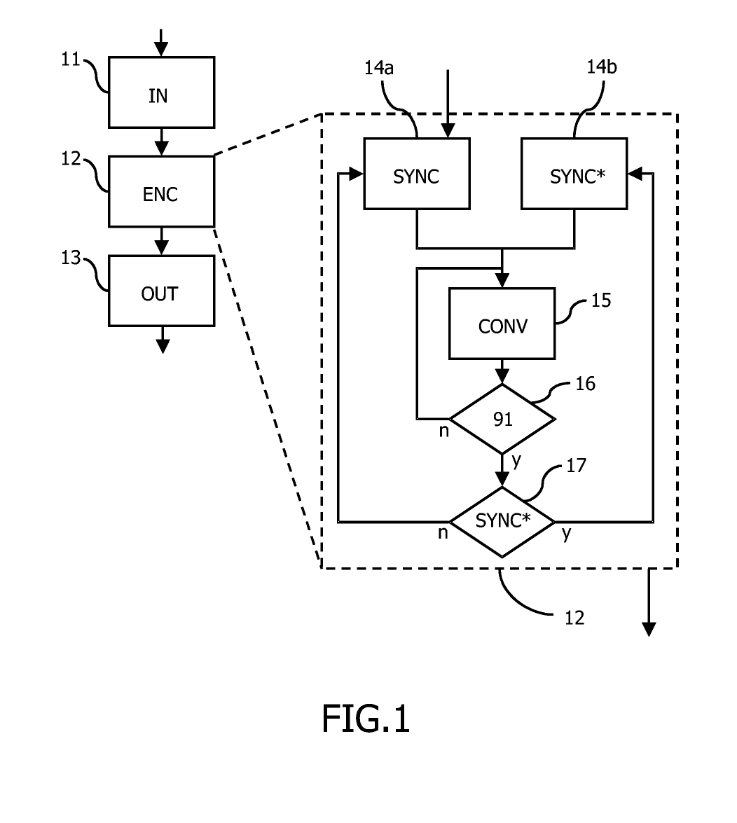

FIG. 1 shows a flow diagram of a first method according to the invention,

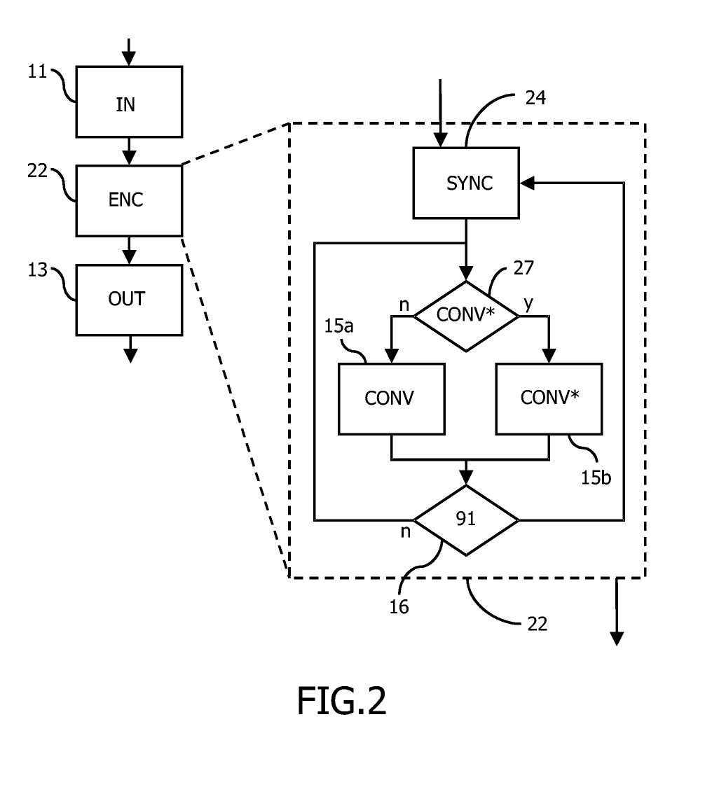

FIG. 2 shows a flow diagram of a second method according to the invention,

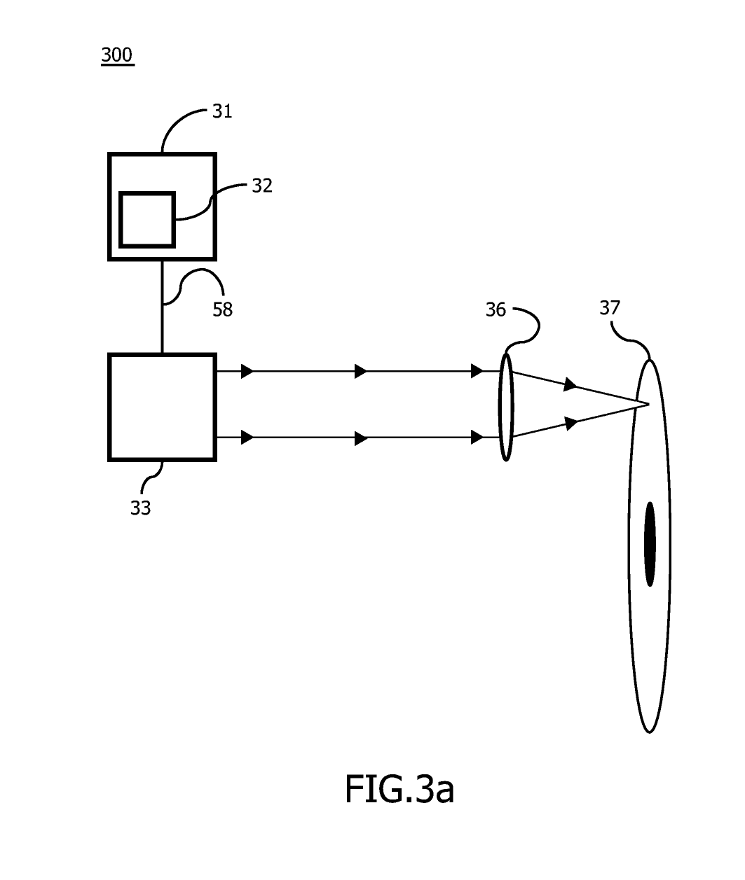

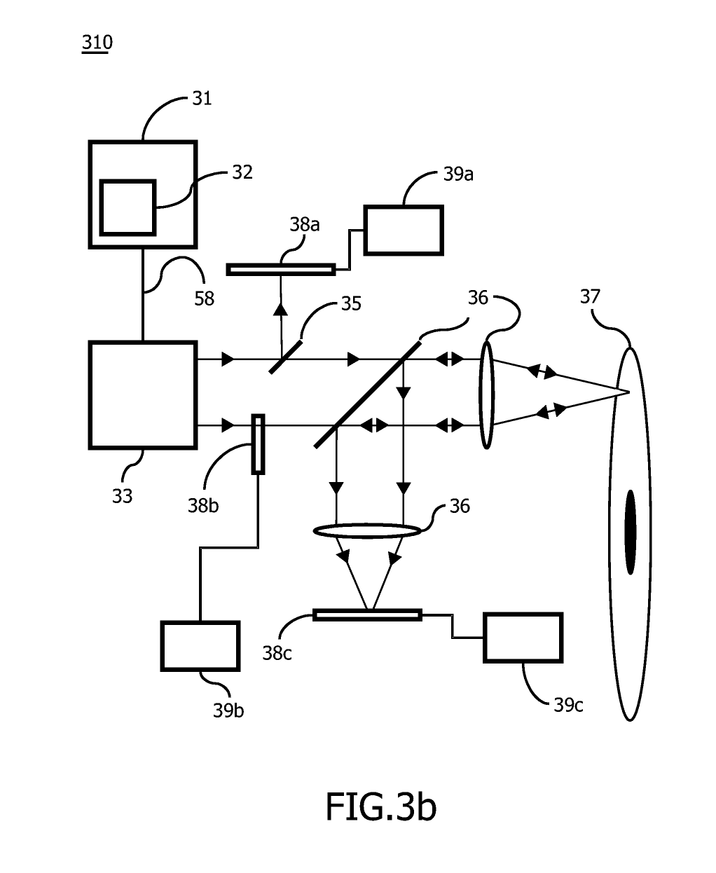

FIG. 3a schematically shows an embodiment of a device according to the invention,

FIG. 3b schematically shows an embodiment of a device according to the invention which also comprises control loops,

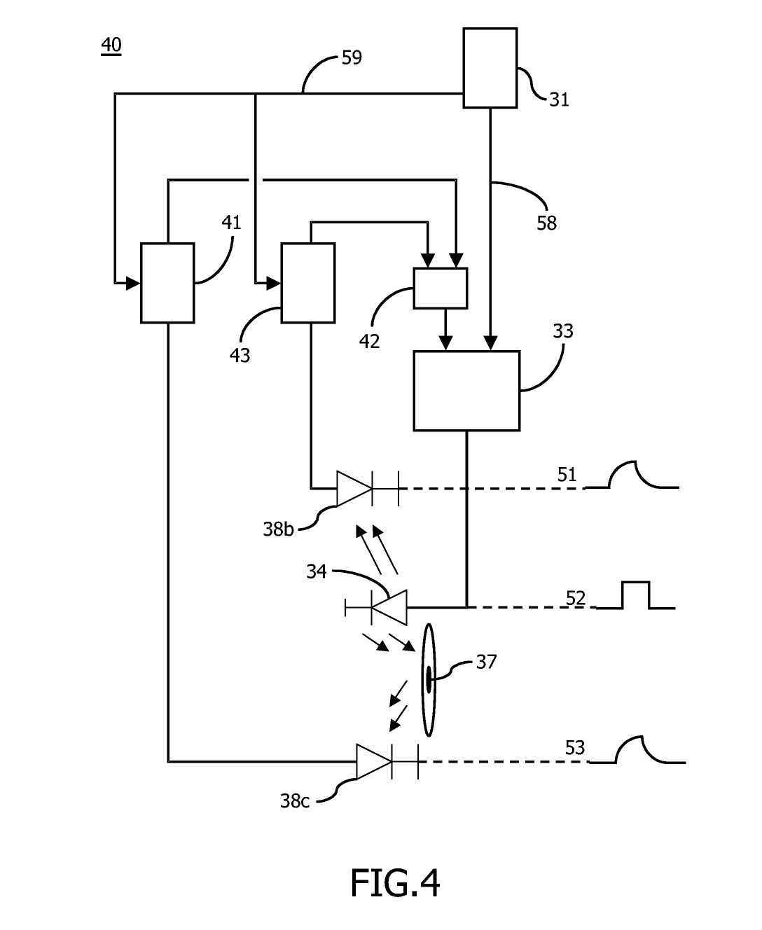

FIG. 4 schematically shows a control circuit which benefits from the method according to the invention, and

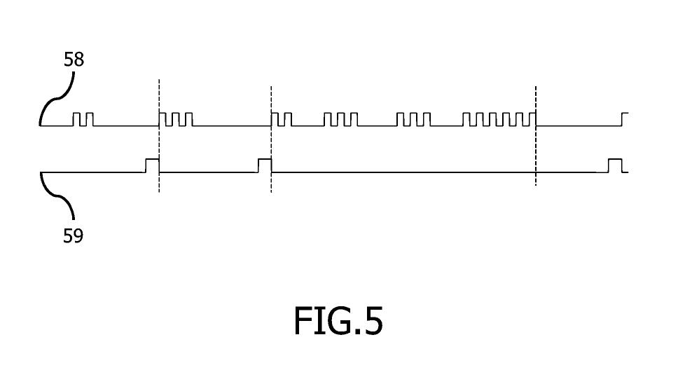

FIG. 5 shows an output signal and a sample signal.

FIG. 1 shows a flow diagram of a first method according to the invention. The method comprises three main steps. At an input step 11 user data is received. The user data may be analogue or digital. The user data may comprise any information someone would like to store on a record carrier, such as music, video or financial data. At an encoding step 12 the user data is encoded according to a predetermined encoding scheme. During the encoding additional detectable signal elements are provided in the encoded user data, for limiting the distance between the detectable elements. At a conversion step 13 the encoded user data is converted to an output signal. The output signal may be used by a storage device, such as a DVD+R writer, for storing the encoded data on a data carrier. In general all storage devices which encode data using a predetermined encoding scheme which results in a code with irregular distances between detectable signal elements with equal signal values and at least a predetermined run length may perform the method according to the invention. In the following the method will be described for performing in a DVD+R or DVD+RW writer, but other storage devices may also advantageously use the method.

When the user data is received it is encoded in an encoding step 12 of which a detailed view is provided in FIG. 1. The user data is an 8-bit digital signal. For example, according to the ECMA-349 or the ECMA-337 standard, the 8 bit bytes at the input are transformed in 16-bit code words using a conversion table. According to the ECMA standards, the encoded signal comprises a 32 bit synchronization pattern after every 1456 channel bits. Thus after every 91 16-bit code words the output code comprises a 32-bit synchronization code (SYNC). According to the ECMA-standards, the SYNCs comprise a signal element with a run length of 14 (1-14). Some control loops use the I-14s of the synchronization pulses for sampling. For such control loops the encoding step 12 may comprise the following steps:

First at step 14a a SYNC code is provided in the output code. According to the encoding scheme the SYNC code comprises an 1-14 signal element. The polarity (high or low signal value) of the I-14 is determined by the rules of the encoding scheme. It is to be noted that other encoding schemes may use more than two different signal values.

Then at step 15 an 8-bit byte is converted to a 16-bit code word, using a conversion table.

At step 16 it is checked whether already 91 bytes have been converted. If not, the next byte is converted at step 15.

After conversion of 91 bytes, the distance to the last provided 1-14 with the desired signal value is evaluated at step 17.

At step 14b, the distance to the last provided detectable signal element is measured and compared to a maximum allowable distance. If an I-14 with the desired signal value is required for guaranteeing that the distance between two consecutive I-14s with the desired signal value will not exceed a predetermined limit then a SYNC code with such an I-14 is forced in the encoded user data. Such an I-14 is provided even if the predetermined encoding scheme would prescribe another SYNC code. The predetermined limit may be expressed in a number of channel bits. The limit may, e.g., be 3*1488 channel bits, which means that an I-14 with the desired polarity is required once in every three SYNCs.

If the distance to the last provided detectable element does not exceed the predetermined limit, at step 14a a SYNC code is provided according to the predetermined encoding scheme.

Then the encoder returns to step 15 for transforming other bytes of user data.

FIG. 2 shows a flow diagram of a second method according to the invention. The second method is similar to the first method. The differences between the two methods are in the respective encoding steps 12 and 22. In the second method, the run length and signal value of certain signal elements are influenced by taking advantage of some choices which have to be made for the transformation of the user data into encoded data.

In the DVD standard the conversion table comprises four different output codes for each input code. The DVD standard prescribes that the DCC (dc component suppression control) algorithm drives the selection of encoded data words. The DCC should do this such that the absolute value of the DSV (digital sum value) at any positions is minimized. The DSV equals the difference between the number of written ONEs and written ZEROs. A minimum DSV is important for several control loops like the loop that controls the slice-level of the hf-data. The DCC algorithm thus determines which one of the four output codes is used for encoding an input code. However, the inventors have seen that there is some margin here. Also in case incidentally a non-optimal data pattern is selected in disagreement of the standard encoding scheme, it will be possible to keep the DSV close to zero over time. It will depend on the bandwidth and the sensitivity of the DSV related control loops, how much we can deviate from the standard encoding scheme. It is to be noted that the providing of additional detectable signal elements at certain positions in the encoded user data may be compensated by deliberately providing non-detectable signal elements at other positions. Thus the term ‘additional’ does not necessarily mean that the complete resulting code comprises more detectable signal elements than prescribed by the predetermined encoding scheme.

The encoding step 22 of the second method comprises the following steps:

First at step 24 a SYNC code is provided in the output code.

Then at step 27 the distance to the last provided detectable signal element is evaluated.

If a detectable signal element is required for limiting the distance between the detectable signal elements, and such a signal element is available from the conversion table, then it is provided in the output code at step 15b. Such a signal element is provided even if the predetermined encoding scheme would prescribe another one.

If no detectable signal element is required yet, at step 15a an 8-bit bytes is converted to a 16-bit code word which is selected from the conversion table in accordance with the encoding scheme.

At step 16 it is checked whether already 91 bytes have been converted. If not, the encoder returns to step 27.

After conversion of 91 bytes, the encoder returns to step 24 for inserting the next SYNC code.

Obviously, also combinations of the, methods shown in FIG. 1 and FIG. 2 may be used for guaranteeing the occurrence of detectable signal elements while deviating from the predetermined encoding scheme as little as possible.

FIG. 3a schematically shows an embodiment of a device 30 according to the invention. The device 300 comprises an input for receiving user data. From the input the user data is sent to the encoder 31. The encoder 31 encodes the data according to a predetermined encoding scheme, such as the standard DVD+R(W) encoding scheme. An encoding control unit 32 controls the providing of detectable signal elements in the output code. The encoding is performed as described above with reference to FIG. 1 and FIG. 2. The encoder 31 is coupled to a laser driver 33 and provides the converted signal. The laser driver 33 turns the converted signal into a laser power. The light from the laser is focused on the data carrier (e.g. an optical disc 37 as in FIG. 3) using optical elements 36, such as lenses and mirrors. Depending on the laser power, pits or lands are written onto the disc 37. The pattern of the pits and lands corresponds to the output code of the encoder 31.

FIG. 3b schematically shows an embodiment of a device 310 according to the invention. This device 310 comprises all elements of the device 300 shown in FIG. 3 and more. In the device 310 control loops sample the laser power and use the sampled signal for adjusting write parameters. The write parameters are used for controlling the laser driver 33 and control or adjust, for example, an amplitude of the write power or bias power of the laser. As described above, such control loops may need to sample detectable signal elements with specific longer run lengths and/or specific signal values. Such control loops may include a laser power level control loop for adjusting a laser power threshold and writing level, an optimum power control loop for control of the laser power on the disc (e.g. for corrections for fingerprints on the disc), servo loops or wobble loops. These control loops comprise a photosensitive diode 38a, 38b, 38c for converting laser power to an electronic signal. Depending on the architecture of the control loop and the write parameter it controls the photosensitive diode receives light directly from the laser (38b), via optical elements 35 (38a) or after reflection at the surface of the disc 37 (38c). Circuitry 39a, 39b, 39c, coupled to the photosensitive diodes 38a, 38b, 38c samples the incident laser power and adjust the write parameters.

FIG. 4 schematically shows an exemplary control circuit 40 which benefits from the method according to the invention. The input data is encoded by the encoder 31. The output signal 58 from the encoder 31 is sent to the laser driver 33. The laser driver 33 converts the output signal 58 and sends a control signal 52 to a laser diode 34. The control signal 52 is a digital signal with sharp transitions from low signal values (bias power level) to high signal values (write power level). The laser diode 34 provides an optic signal corresponding to the control signal 52. The optic signal from the laser diode actually creates the data pattern on the disc 37.

The control circuit 40 comprises two control loops which are described in detail below. The first control loop is a laser power control loop. During writing of a DVD+R disc, the laser power control loop must control two power levels of the optic signal; the bias power, which is a low power level that does not cause any writing effect but does allow some reading from the disc 37, and an accurate write power level that causes the actual pits. The information for both levels may be extracted from one feedback signal 51. In DVD+RW devices, the control signal may also comprise signal elements with an intermediate signal value (erase power level) for erasing data on the disc. The laser power is measured using a first photosensitive diode 38b which receives a fraction of the laser light directly from the laser diode 34 and converts it into a current. An example of a feedback signal 51 measured by the photosensitive diode 38b is also shown in FIG. 4. The settling behaviour of the photosensitive diode 38b might be insufficient to allow accurate sampling. Therefore the feedback signal 51 does not show the sharp transitions from high to low and vice versa which can be seen in the control signal 52. For accurate sampling, long enough signal elements are required for allowing the feedback signal 51 to settle before being sampled by a sample and hold circuit 43. The sampled signal value is provided to a write parameter correction unit 42 for adjusting the write parameters. The adjusted write parameters are then supplied to the laser driver 33.

With the method and the device according to the invention detectable signal elements can be guaranteed to occur within a certain time frame. As a result the control loop can sample the feedback signal 51 at a constant high rate and loop stability is high.

The second control loop controls the laser power for adapting the laser power for fingerprints and black dots on the disc 37 surface. This control loop is similar to the laser power control loop described above. A second photosensitive diode 38c measures the laser power indirectly, via the disc 37 surface. The feedback signal 53 from the second photosensitive diode 38c is sampled by sample and hold circuit 41. The sampled signal is provided to the correction unit 42.

For reliable sampling the laser power values corresponding to the detectable signal elements the sample and hold circuits 41 and 43 should know when such a detectable signal element is provided. If the sample and hold circuits 41 and 43 would sample the feedback signals 51 and 53 at random moments, the correction unit 42 would not know whether a bias power level, a write power level or a transition between those levels is sampled and the samples would be useless for controlling the writing process. Also sampling at a constant rate would be problematic because of the irregular distances between the detectable elements. Therefore the encoder 31 provides a sample trigger signal 59 whenever a detectable signal element is provided.

In FIG. 5 part of the output signal 58 and the sample trigger signal 59 are shown. The output signal 58 comprises three signal elements with a run length that is long enough to be accurately sampled. The sample trigger signal 59 provides a trigger signal at the end of said detectable signal elements. This allows the control circuit 40 to sample the feedback signals 51, 53 at the right moment and benefits the stability of the control loop.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “comprise” and its conjugations does not exclude the presence of elements or steps other than those stated in a claim. The article “a” or “an” preceding an element does not exclude the presence of a plurality of such elements. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measures cannot be used to advantage.

1. A method for providing an output signal (58) for storing of user data on a data carrier (37), the method comprising the steps of:
receiving (11) the user data,
encoding (12) the user data according to a predetermined encoding scheme resulting in irregular distances between detectable signal elements which have equal signal values and at least a predetermined run length, and
converting (13) the encoded user data to the output signal (58),
the step of encoding comprising providing (14b, 15b) additional detectable signal elements in the encoded user data in disagreement with the encoding scheme, for limiting the distance between the detectable signal elements.

2. A method as claimed in claim 1, wherein
the encoded user data comprises sequences of signal elements which sequences represent encoded bits of the user data,
said signal elements of the sequences have a signal value and a run length according to the predetermined encoding scheme, and wherein
the encoding comprises providing (15b) the sequences of signal elements with the additional detectable signal elements in disagreement with the encoding scheme.

3. A method as claimed in claim 1, wherein
the encoded user data comprises synchronization pulses comprising signal elements with at least the predetermined run length,
the irregular distances resulting from irregular signal values for said signal elements of the synchronization pulses, and wherein
the encoding comprises providing (14b) synchronization pulses with the additional detectable signal elements in disagreement with the encoding scheme.

4. A device (300, 310) comprising:
an input for receiving user data,
an encoder (31) for encoding the user data according to a predetermined encoding scheme resulting in irregular distances between detectable signal elements with equal signal values and at least a predetermined run length,
an encoding control unit (32) for providing additional detectable signal elements in the encoded user data in disagreement with the encoding scheme, for limiting the distance between the detectable signal elements, and
an output unit for converting the encoded user data to an output signal (58) for storing of the user data on a data carrier (37).

5. A device (300, 310) as claimed in claim 4, wherein
the encoder (31) is arranged for providing the encoded user data with sequences of signal elements which sequences represent encoded bits of the user data,
said signal elements of the sequences have a signal value and a run length according to the predetermined encoding scheme, and wherein
the encoding control unit (32) is arranged for providing sequences of signal elements with the additional detectable signal elements in disagreement with the encoding scheme.

6. A device (300, 310) as claimed in claim 4, wherein
the encoder (31) is arranged for providing the encoded user data with synchronization pulses comprising signal elements with at least the predetermined run length, and
the irregular distances result from irregular signal values for said signal elements of the synchronization pulses, and wherein
the encoding control unit (32) is arranged for providing synchronization pulses with the additional detectable signal elements, in disagreement with the predetermined encoding scheme.

7. A device (300, 310) as claimed in claim 4, further comprising:
a laser drive unit (33, 34) for receiving the output signal (58) and providing a laser signal for writing the encoded user data on the data carrier (37), and
at least one feedback circuit (40) for sampling the laser signal and for adjusting a write parameter according to a sampled value of the laser signal corresponding with the detectable signal elements.

8. A device (310) as claimed in claim 7, wherein the encoder (31) is arranged for providing a sample trigger signal (59) to the feedback circuit (40) for enabling the feedback circuit (40) to sample a value of the laser signal (51, 53) corresponding with the detectable signal elements.

9. A device (310) as claimed in claim 7, wherein the write parameter is a threshold power level and/or writing power level of a laser (34).

10. A device (310) as claimed in claim 7, wherein the feedback circuit (40) is arranged for controlling a laser power on the data carrier (37).

11. A data carrier (37) comprising user data encoded according to a predetermined encoding scheme,
the predetermined encoding scheme resulting in irregular distances between detectable signal elements with equal signal values and at least a predetermined run length,
the encoded user data comprising additional detectable signal elements in disagreement with the encoding scheme, for limiting the distance between the detectable signal elements.
